(19) United States
(12) Patent Application Publication
(10) Pub. No.: US 2008/0067082 A1
(43) Pub. Date: Mar. 20, 2008

(54) Containing structure of USB plugging-and-locking head

(75) Inventor: Chien-Pin Huang, Taipei (TW)

Correspondence Address: TROXELL LAW OFFICE PLLC;SUITE 1404, 5205 LEESBURG PIKE, FALLS CHURCH, VA, 22041, US

(73) Assignees: Guann Tau International Corp.; Jin Chyun Mei Enterprises Co., Ltd.

(21) Appl. No.: 11/790,881

(22) Filed: Apr. 27, 2007

(30) Foreign Application Priority Data
Sep. 14, 2006 (TW) 95216402

(51) Int. Cl. H05K 7/00

(52) U.S. Cl. 206/1.5; 361/747

(57) ABSTRACT

A containing structure of USB plugging-and-locking head including a USB plugging-and-locking seat, at least a USB plugging-and-locking head, and a lid is disclosed. The USB plugging-and-locking seat has a containing space and a connecting portion extending out from an end of the USB plugging-and-locking seat. One end of the USB plugging-and-locking head can select either to combine with or to separate from the connecting portion, and the USB plugging-and-locking head can position in the containing space. The lid can perform a linear displacement movement or a rotational movement to close the containing space. By making use of the containing space, one can has the several USB plugging-and-locking heads contain in the USB plugging-and-locking seat for preventing the USB plugging-and-locking heads from being lost, convenient to take out for use, as well as combined with the USB plugging-and-locking seat for use.

### BACKGROUND OF THE INVENTION

1. Field of the Invention

The invention relates to a containing structure of USB plugging-and-locking head, and more particularly, to a containing structure of USB plugging-and-locking head that is capable of containing a multiplicity of USB plugging-and-locking heads.

2. Description of the Prior Art

Science and technology change with each passing days. Following the popularization of the personal computer as well as the flourishing of the 3C-product, in the light of the peripherals having various specifications, components such as joints, plugging heads, and signal cables having different shapes and specifications, weed through the old and to bring forth the new. Ever since the issue of Windows 98 of the Micro-Soft Company, this new data transmission interfaces—the USB (Universal Serial Bus) has become a very hot issue.

In reality, the USB specification has gone to the public by Intel Company as early as 1996, but the operation system at that time did not support the driving function of this interface. The position of this new interface was not definite until the Windows 98 appeared to the market. USB is a specification of a general-purpose interface; it can connect to the peripherals such as the keyboard, the mouse, the joystick etc. The connector of the keyboard in the past is a design of a circular one having six pins therein. The mouse has two different connectors having different specifications—a PS2 circular connector and a rectangular connector having 9 pins. This diversified design makes the users create a lot of trouble when it comes to implementing a computer or changing equipments. The function of the USB is to unify these diversified connectors.

The conveniency of the USB relatively results in the seriousness of data let out. Anyone with a portable disc can plug in the USB port of the host computer to steal a copy of the data stored therein. Therefore, a locking device of USB port appeared on the market was developed. FIG. 1 is an isometric exploded view of the structure of the locking device of a USB port of the prior art. As shown in FIG. 1, the locking device (1) of the USB port on the market of the prior art includes a moving head portion (11), a main body (12), a sliding switch (13), a connecting block (14) as well as a two-hook body (15). The sliding switch (13) positioned on the main body (12) can move on the first position (91) and the second position (92). The connecting block (14) secures at an end surface of the main body (12) and extends out of the end surface. The two-hook body (15) inter-locked with the sliding switch (13) are positioned within the main body (12).

The hook portion (151) of the two-hook body (15) is within the connecting block (14) when the sliding switch (13) positions at the first position (91). Therefore, the connecting block (14) can separate from the moving head portion (11), thus make the moving head portion (11) positions at the USB port (not shown in the Figure) to perform the locking of the USB port in order to prevent the data from being read. The hook portion (151) of the two-hook body (15) will extends out of the connecting block (14) as the sliding switch (13) positions at the second position (92). Therefore, the connecting block (14) can connect to the moving head portion (11). By the use of the main body (12) to carry the moving head portion (11) out of the USB port, the USB port can be opened to be used.

The above-mentioned locking device of USB port on the market of the prior art has the following demerits: since the moving head (11) occupies a small volume of space, it is apt to be lost and not easy to be kept in good condition if it is separated from the two-hook body (15). Once it is lost, one needs to buy a new one. Therefore, it has been an urgent plan and improvement project for the manufacturers to resolve the above-mentioned problems.

### SUMMARY OF THE INVENTION

In light of the above-mentioned demerits of the prior art, the invention provides a containing structure of USB plugging-and-locking head that aims to ameliorate at least some of the demerits of the prior art or to provide a useful alternative.

The primary objective of the invention is to provide a containing structure of USB plugging-and-locking head to achieve the efficacy of facilitating the loading of the USB plugging-and-locking heads making the USB plugging-and-locking heads not apt to be lost.

The secondary objective of the invention is to provide a containing structure of USB plugging-and-locking head to divide the containing space into several spaces by making use of the partitions to achieve the efficacy of simultaneously loading the multiplicity of USB plugging-and-locking heads.

In order to achieve the above-mentioned objectives, the invention provides a containing structure of USB plugging-and-locking head that includes a USB plugging-and-locking seat, at least a USB plugging-and-locking head, and a lid. The USB plugging-and-locking seat has a containing space and a connecting portion extending out from an end of the USB plugging-and-locking seat. One end of the USB plugging-and-locking head can select either to combine with or to separate from the connecting portion, and the USB plugging-and-locking head can position in the containing space. The lid can perform a linear displacement movement or a rotational movement to close the containing space. By making use of the containing space, one can has the several USB plugging-and-locking heads contain in the USB plugging-and-locking seat for preventing the USB plugging-and-locking heads from being lost, convenient to take out for use, as well as combined with the USB plugging-and-locking seat for use.

The accomplishment of this and other objectives of the invention will become apparent from the following description and its accompanying drawings of which:

### BRIEF DESCRIPTION OF THE DRAWINGS

FIG. 1 is an isometric exploded view of the structure of the locking device of a USB port of the prior art;

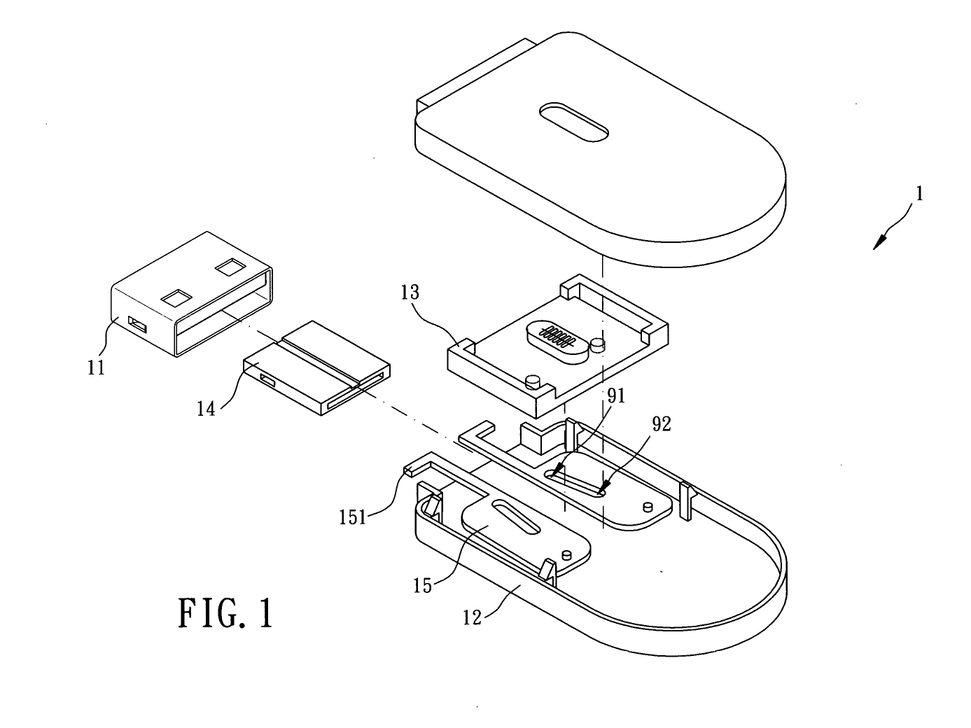

FIG. 2 is an isometric exploded view of the USB plugging-and-locking head of the preferred embodiment of the invention;

FIG. 3 is an isometric exploded view of the USB plugging-and-locking head of the usage status of the invention;

FIG. 4 is an isometric exploded view of the action of the lid of the USB plugging-and-locking head of the invention;

FIG. 5 is a top view of the action of the lid of the USB plugging-and-locking head of the invention;

FIG. 6 is an isometric exploded view of the USB plugging-and-locking head of another embodiment of the invention;

FIG. 7 is a side view of the schematic structural diagram of the action of the lid shown in FIG. 6.

### DETAILED DESCRIPTION OF THE PREFERRED EMBODIMENT

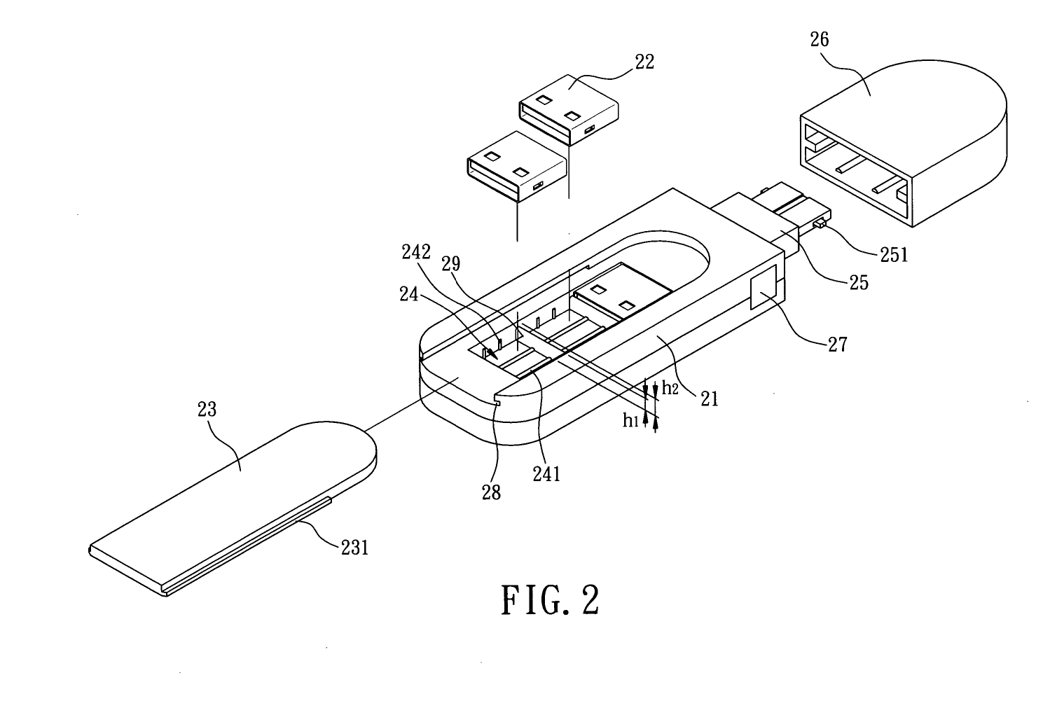

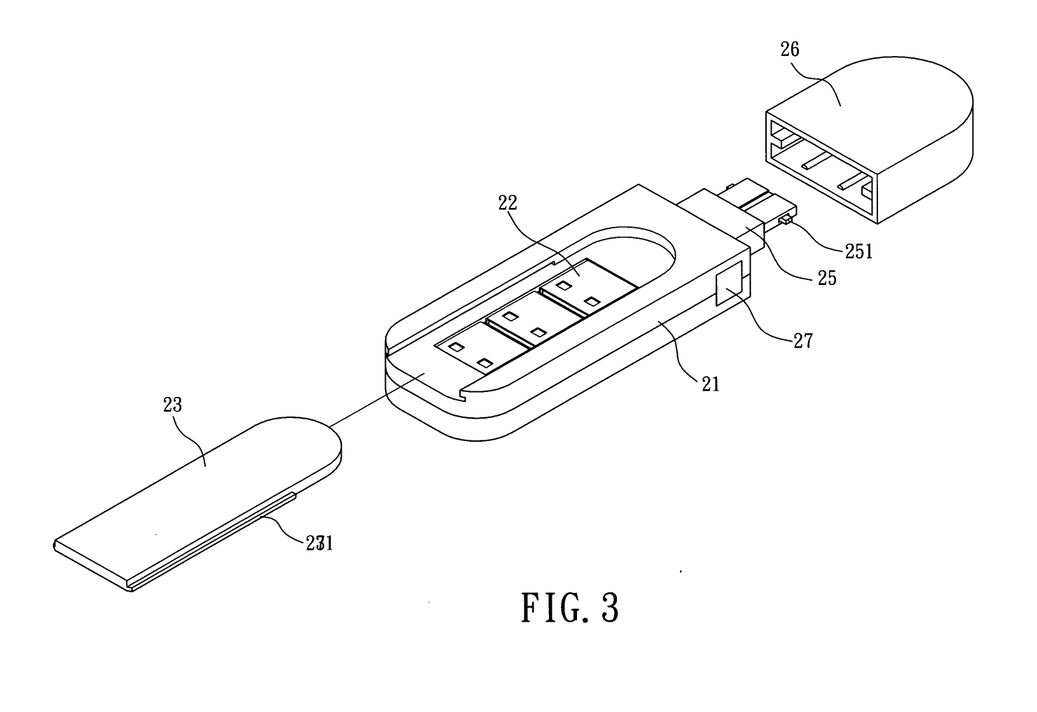

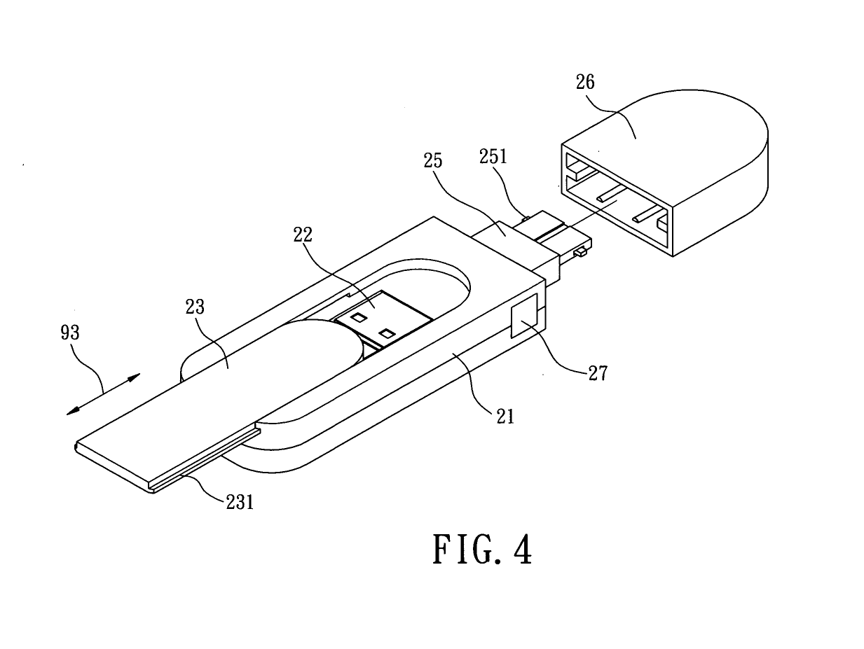

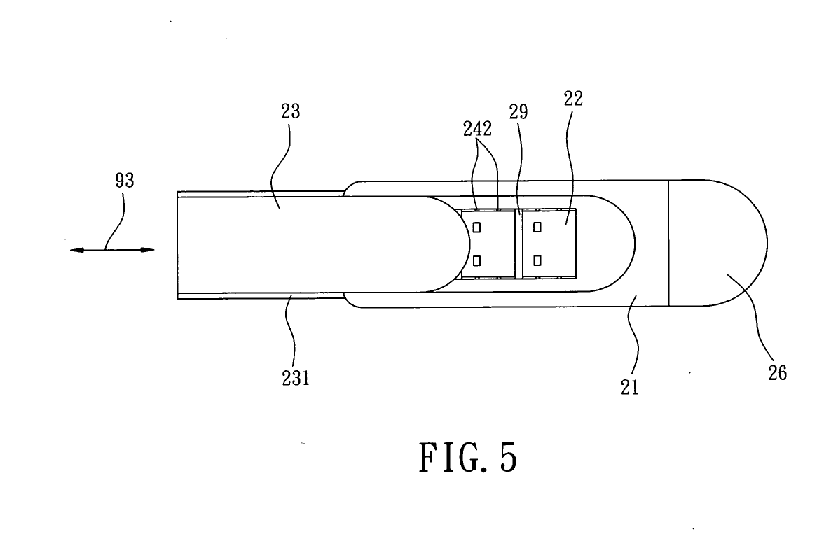

FIG. 2 through FIG. 4 are isometric exploded views of the USB plugging-and-locking head, its usage status, the action of its lid of the preferred embodiment of the invention while FIG. 5 is a top view of the action of the lid of the USB plugging-and-locking head of the invention. As shown in FIG. 2 through FIG. 5, the containing structure (2) of the USB plugging-and-locking head of the invention includes a USB plugging-and-locking seat (21), at least a USB plugging-and-locking head (22) and a lid (23). The USB plugging-and-locking seat (21) has a containing space (24), a connecting portion (25), and a pressing switch (27). The connecting portion (25) being extended from an end of the USB plugging- and-locking seat (21) has a two-hook portion (251). By exerting a force to the pressing switch (27), the two-hook portion (251) is hidden in the connecting portion (25) while releasing the exerting force, the two-hook portion (251) is restored back to the protruded position out of the connecting portion (25) through its inherent resilient force. In the preferred embodiment of the invention, the containing structure (2) further includes a cap (26) that is capable of covering on the USB plugging-and-locking seat (21) for closing the connecting portion (25) as well as separating from the USB plugging-and-locking seat (21) to open the connecting portion (25) for use.

An end of the USB plugging-and-locking head (22) can have a choice to combine with the connecting portion (25) or to separate from the connecting portion (25). In other words, when a force is exerted to the pressing switch (27), the two-hook portion (251) is hidden within the connecting portion (25). At this moment, the USB plugging-and-locking head (22) can perform displacement movement on the top of the connecting portion (25). However, when the exerted force is released, the pressing switch (27) will be restored through its inherent resilient force making the two-hook portion (251) protrude out of the connecting portion (25) and secure the USB plugging-and-locking heads (22) in position. The USB plugging-and-locking heads (22) can be placed in the containing space (24) when the USB plugging-and-locking heads (22) are unloaded. In the preferred embodiment of the invention, the containing space (24) has at least a partition (29) to accommodate a plurality of bottom ribs (241) positioned on the bottom surface of the containing space (24) as well as a plurality of side ribs (242) positioned on the side surface of the containing space (24). All of these ribs make the USB plugging-and-locking heads (22) position in the containing space (24). In addition, since the height of the partition (29) “h1” is smaller that that of the containing space (24) “h2”, i.e. h1<h2, the arrangement is capable of facilitating the user to load and unload the USB plugging-and-locking heads (22). In the preferred embodiment of the invention, the containing space (24) can contain three USB plugging-and-locking heads (22), and the containing space (24) can certainly contain some other numbers of the USB plugging-and-locking head (22). This kind of variation is understood by those people skilled in the art without departing from the spirit and range of the invention, thereby, it is not necessary to go into detail here.

The lid (23) can be connected to the USB plugging-and-locking seat (21) to perform the closing action of the containing space (24). As the lid (23) has at least a guided portion (231), the USB plugging-and-locking seat (21) has at least a guided groove (28) that is corresponding to the containing space (24), thereby the guided groove (28) is capable of providing the connecting action for the guided portion (231). Consequently, the lid (23) is capable of performing displacement movement along the extended direction (93) of the guided portion (231).

In the following other embodiments, same numerals are assigned for most of the elements since most of them are the same as those of the above-mentioned embodiments, thereby it is not necessary to go into detail here. It is understood that same numerals are assigned for similar elements, however, they are suffixed with an English alphabet for differentiation and are depicted in the light of their difference.

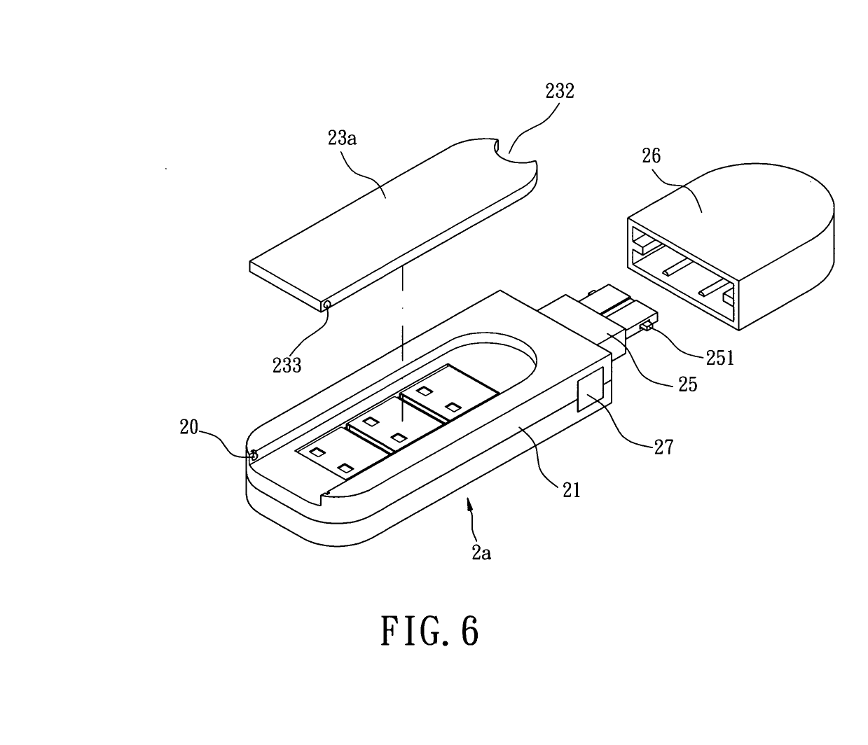

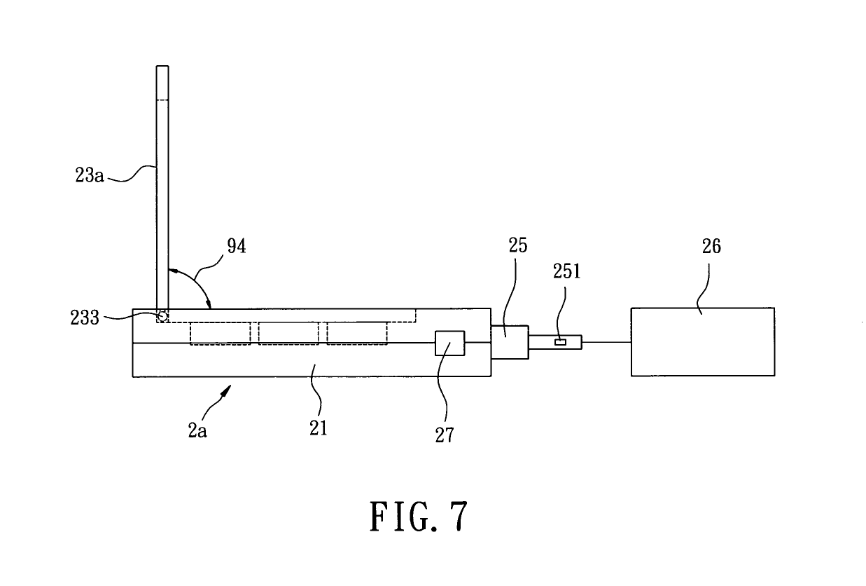

FIG. 6 is an isometric exploded view of the USB plugging-and-locking head of another embodiment of the invention while FIG. 7 is a side view of the schematic structural diagram of the action of the lid shown in FIG. 6. As shown in FIG. 6 and FIG. 7, in the preferred embodiment of the invention, the containing structure (2a) of the USB plugging-and-locking head (22) further includes a pivot recess (20) while the lid (23a) has at least a shaft portion (233) protruding out from the lid (23a). When the shaft portion (233) is pivotally connected to the pivot recess (20), the user is capable of exerting a force at a recess (232) at an end of the lid (23a) to perform rotational movement with respect to the shaft portion (233).

It will become apparent to those people skilled in the art that various modifications and variations can be made to the structure of the invention without departing from the scope or spirit of the invention. In view of the foregoing description, it is intended that all the modifications and variation fall within the scope of the following appended claims and their equivalents.

What is claimed is:

1. A containing structure of USB plugging-and-locking head comprising:
a USB plugging-and-locking seat having a containing space and a connecting portion extending from the USB plugging-and-locking seat; and
at least a USB plugging-and-locking head having its one end either combined to or separated from the connecting portion, and the USB plugging-and-locking head can be positioned in the containing space.

2. The containing structure of USB plugging-and-locking head as claimed in claim 1, wherein the containing structure further comprises a cap capable of connecting to the USB plugging-and-locking seat for performing the closing of the connecting portion.

3. The containing structure of USB plugging-and-locking head as claimed in claim 1, wherein the containing structure further comprises a lid capable of connecting to the USB plugging-and-locking seat for performing the closing of the containing structure.

4. The containing structure of USB plugging-and-locking head as claimed in claim 3, wherein the lid has at least a guided portion making the lid perform displacement movement along the guided portion.

5. The containing structure of USB plugging-and-locking head as claimed in claim 4, wherein the USB plugging-and-locking seat has at least a guided groove for providing connection to the guided portion, and the guided groove is corresponding to the containing space.

6. The containing structure of USB plugging-and-locking head as claimed in claim 1, wherein the containing space has at least a partition that is capable of making the USB plugging-and-locking head position in the containing space.

7. The containing structure of USB plugging-and-locking head as claimed in claim 3, wherein the lid has at least a shaft portion making the lid capable of performing rotational movement with respect to the shaft portion.
